(19) United States
(12) Patent Application Publication
(10) Pub. No.: US 2026/0171169 A1
(43) Pub. Date: Jun. 18, 2026

(54) MEMORY DEVICE, OPERATING METHOD OF MEMORY DEVICE, AND MEMORY SYSTEM

(71) Applicant: SK hynix Inc., Icheon-si Gyeonggi-do (KR)

(72) Inventor: Tai Kyu KANG, Icheon-si Gyeonggi-do (KR)

(73) Assignee: SK hynix Inc., Icheon-si Gyeonggi-do (KR)

(21) Appl. No.: 19/193,222

(22) Filed: Apr. 29, 2025

(30) Foreign Application Priority Data
Dec. 16, 2024 (KR) 10-2024-0186903

(51) Int. Cl. G11C 16/32; G11C 16/04

(52) U.S. Cl. CPC G11C 16/32; G11C 16/0483

(57) ABSTRACT

The present disclosure relates to a memory device, a method of operating the memory device, and a memory system. A memory device includes a plurality of memory planes each including a plurality of memory blocks, a plurality of sub-peripheral circuits, each corresponding to one of the plurality of memory planes, each of the plurality of sub-peripheral circuits configured to perform various operations on a selected memory block included in a corresponding memory plane among the plurality of memory planes, and a plurality of sub-control logic circuits, each configured to control one of the plurality of sub-peripheral circuits, wherein the plurality of sub-control logic circuits is configured to generate peak current information signals activated during peak current intervals during any of the various operations on the plurality of memory planes, and wherein a period of an internal clock signal is adjusted based on the peak current information signals.

### CROSS-REFERENCE TO RELATED APPLICATION

The present application claims priority under 35 U.S.C. § 119(a) to Korean patent application number 10-2024-0186903 filed on Dec. 16, 2024, in the Korean Intellectual Property Office, the entire contents of which application is incorporated herein by reference.

### BACKGROUND

### 1. Technical Field

The present disclosure relates to a memory system, including but not limited to a memory device, an operating method of the memory device, and a memory system.

### 2. Related Art

A storage device stores data under control of a host device such as a computer or a smartphone. The storage device includes a memory device in which data is stored and a memory controller that controls the memory device. Memory devices are characterized as volatile memory devices and non-volatile memory devices.

Volatile memory devices retain stored data only while power is supplied, and stored data is no longer retained when the power supply is interrupted. Volatile memory devices include static random access memory (SRAM), dynamic random access memory (DRAM), and the like.

Non-volatile memory devices are memory devices in which stored data is retained even when power is interrupted, such as Read Only Memory (ROM), Programmable ROM (PROM), Electrically Programmable Rom (EPROM), Electrically Erasable and Programmable Rome (EEPROM), and Flash Memory.

### SUMMARY

According to an embodiment, a memory device may include a plurality of memory planes, each including a plurality of memory blocks, a plurality of sub-peripheral circuits, each corresponding to one of the plurality of memory planes, each of the plurality of sub-peripheral circuits configured to perform various operations on a selected memory block included in a corresponding memory plane among the plurality of memory planes, and a plurality of sub-control logic circuits, each configured to control one of the plurality of sub-peripheral circuits, wherein the plurality of sub-control logic circuits is configured to generate peak current information signals activated during peak current intervals during any of the various operations on the plurality of memory planes, respectively, and wherein a period of an internal clock signal is adjusted based on the peak current information signals.

According to an embodiment, a method of operating a memory device may include generating an internal clock signal based on an external clock signal, generating a plurality of internal commands that controls various operations on each of a plurality of memory planes, performing the various operations on the plurality of memory planes concurrently in an interleaved manner based on the plurality of internal commands, generating a plurality of peak current information signals corresponding to the plurality of memory planes and including information on peak current intervals during any of the various operations on the plurality of memory planes, and adjusting a period of the internal clock signal based on the plurality of peak current information signals.

According to an embodiment, a memory system may include a plurality of memory devices, and a memory controller configured to control various operations on the plurality of memory devices, wherein each of the plurality of memory devices is configured to generate and output information about a peak current interval during the various operations, and wherein the memory controller is configured to generate and output an external clock signal having an adjusted a period based on information about the peak current interval received from each of the plurality of memory devices.

According to an embodiment, a method may include generating an internal clock signal based on an external clock signal; generating a plurality of commands that control a plurality of operations concurrently performed on each of a plurality of memory planes; generating a plurality of peak current information signals including information on a peak current intervals during the plurality of operations; and adjusting a period of the internal clock signal based on the plurality of peak current information signals.

### BRIEF DESCRIPTION OF THE DRAWINGS

FIG. 1 is a diagram illustrating a memory system according to an embodiment;

FIG. 2 is a diagram illustrating signals exchanged between a memory controller and a memory device according to an embodiment;

FIG. 3 is a detailed diagram of a memory device according to an embodiment;

FIG. 4 is a diagram illustrating an embodiment of a memory cell array;

FIG. 5 is a diagram illustrating a memory block according to an embodiment;

FIG. 6 is a diagram of a memory block configured in three dimensions according to an embodiment;

FIG. 7 is a diagram of a memory block configured in three dimensions according to an embodiment;

FIG. 8 is a diagram of a multi-plane structure in a memory device according to an embodiment;

FIG. 9 is a diagram illustrating an embodiment of control logic circuit according to an embodiment;

FIG. 10 is a flowchart illustrating a method of operating a memory system according to an embodiment of the present disclosure;

FIG. 11 is a timing diagram including signals during a method of operating a memory system according to an embodiment of the present disclosure;

FIG. 12 is a flowchart illustrating a method of operating a memory device according to an embodiment of the present disclosure;

FIG. 13 is a timing diagram including signals during a method of operating a memory device according to an embodiment of the present disclosure;

FIG. 14 is a block diagram illustrating a configuration of a computing system according to an embodiment of the present disclosure; and

FIG. 15 is a block diagram illustrating a computing system according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples of embodiments described in this specification.

Terms such as “vertical,” “horizontal,” “top,” “above,” “beneath,” “overlap,” “on,” “side,” “upper,” “lower,” “high,” “low,” “column,” “row,” “level,” and other terms implying relative spatial relationship or orientation are utilized only for the purpose of ease of description or reference to a drawing and are not otherwise limiting.

When one element is identified as “coupled” to another element, the elements may be coupled directly or through at least one intervening element between the elements. When two elements are identified as “directly coupled,” one element is directly coupled to the other element without an intervening element between the two elements.

A memory device, a method of operating the memory device, and a memory system may reduce peak current during operation of the memory device.

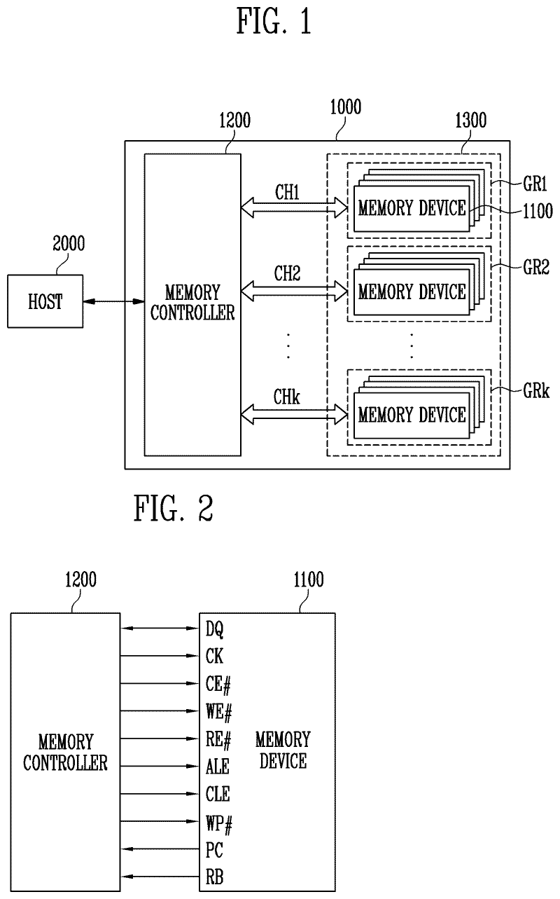

FIG. 1 is a diagram illustrating a memory system 1000 according to an embodiment.

Referring to FIG. 1, the memory system 1000 includes a memory device 1100 in which data is stored and a memory controller 1200 that controls the memory device 1100 in response to a request from a host 2000.

The host 2000 communicates with the memory system 1000 using at least one of various communication methods, such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), NonVolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIM), Load Reduced DIMM (LDRIMM), and the like.

The memory device 1100 is a volatile memory device in which data is lost or not retained when the power supply is cut off or interrupted or a non-volatile memory device in which the data is retained in the absence of power supply. The memory controller 1200 controls the memory device 1100 to perform a program operation, a read operation, and an erase operation. Various operations on the memory device 1100 include the program operation, the read operation, and the erase operation. For example, during a program operation, the memory device 1100 receives commands, addresses, and data from the memory controller 1200 and performs the program operation. During a read operation, the memory device 1100 receives a command and an address from the memory controller 1200 and outputs data stored at a location, for example, a physical address, corresponding to the received address to the memory controller 1200. The memory device 1100 is an individual Integrated Chip (IC) that has been processed into a memory device and may be referred to as a memory chip or a memory die.

The memory system 1000 includes the plurality of memory devices 1100, and the plurality of memory devices are grouped into a plurality of memory device groups 1300 according to a channel coupled to the memory controller 1200. For example, among the plurality of memory devices 1100, memory devices coupled to the memory controller 1200 through a first channel CH1 are referred to as a first group GR1. Among the plurality of memory devices, memory devices coupled to the memory controller 1200 through a second channel CH2 are referred to a second group GR2. Memory devices coupled to the memory controller 1200 through a k-th channel CHk are referred to as a k-th group GRk, where, where k is an integer greater than 1.

Although FIG. 1 illustrates one group as including a plurality of memory devices, one group may include a single memory device 1100.

The memory controller 1200 controls various operations on the memory system 1000 and controls data exchange between the host 2000 and the memory device 1100. For example, when the memory controller receives a command from the host 2000, the memory controller 1200 controls the memory device groups 1300 coupled to each of a plurality of channels CH1 to CHk according to the received command. At the request of the host 2000, the memory controller 1200 programs, reads, or erases data by controlling the memory device groups 1300 coupled to each channel.

Operational periods of the memory devices 1100 included in each of the memory device groups 1300 may overlap. For example, operations on the memory devices 1100 included in the first group GR1, operations on the memory devices 1100 included in the second group GR2, and operations on the memory device 1100 included in the k-th group GRk may be performed with two or more overlapping operational periods.

FIG. 2 is a diagram illustrating signals exchanged between the memory controller 1200 and the memory device 1100, for example, as shown in FIG. 1.

Referring to FIG. 2, the memory controller 1200 exchanges commands, data, and addresses with the memory device 1100 through an input/output pad DQ. For example, the input/output pad DQ may include eight lines to transmit and receive 8 (eight) bits of data, and each of the lines may transmit and receive 1 (one) bit of data.

The memory device 1100 receives an external clock signal through a CK pad CK, receives a chip enable signal through a CE #pad CE #, receives a write enable signal through a WE #pad WE #, receives a read enable signal through an RE #pad RE #, receives an address latch enable signal through an ALE pad ALE, receives a command latch enable signal through a CLE pad CLE, and receives a write protection signal through a WP #pad WP #. The external clock signal is received from the memory controller 1200 as shown in FIG. 1, from which external clock signal an internal clock signal for the memory device 1100 is generated. The memory device 1100 adjusts the cycle or period of the internal clock signal according to the cycle or period of the external clock signal.

The address latch enable ALE signal is a signal through which the memory controller 1200 instructs the memory device 1100 to load an address provided to the memory device 1100 via the input/output pad DQ into an address register. A chip enable signal CE is a signal through which the memory controller 1200 instructs the memory device 1100 to enable or disable one or more memory devices. A command latch enable signal CLE is a signal according to which the memory controller 1200 instructs the memory device 1100 to load a command that is provided to the memory device 1100 through the input/output pad DQ into a command register. A read enable signal RE is a signal according to which the memory controller 1200 instructs the memory device 1100 to transfer data to the memory controller 1200. A write enable signal WE is a signal that indicates transfer of a command, an address, and data.

The memory device 1100 outputs a peak current information signal PC to the memory controller 1200 through a PC pad PC and outputs a ready-busy signal to the memory control 1200 through an RB pad RB. The peak current information signal indicates an operational period with high internal power consumption during a program operation, a read operation, or an erase operation on the memory device 1100. For example, the peak current information signal is activated at a logic high level during a peak current interval in which current consumption exceeds a predetermined value during a program operation, a read operation, or an erase operation on the memory device 1100. The ready-busy signal indicates whether the memory array of the memory device 1100 is in a busy state or an idle state.

Although FIG. 2 illustrates a coupling relationship between one memory device 1100 and the memory controller 1200, the input/output pad DQ, the CE #pad CE #, the WE #pad WE, the RE #pad RE #, the ALE pad ALE, the CLE pad CLE, and the WP #pad WP #form one channel among channels CH1 to CHk, and the memory controller 1200 and one of the memory device groups 1300 of FIG. 1 are coupled through the formed channel among CH1 to CHk.

The memory controller 1200 receives a plurality of peak current information signals from the plurality of memory devices 1100 included in the memory device groups 1300 in FIG. 1. The memory controller 1200 receives the plurality of peak current information signals corresponding to the plurality of memory devices 1100. The memory controller 1200 adjusts a period of an external clock signal based on the plurality of received peak current information signals. For example, the memory controller 1200 adjusts the period of the external clock signal based on the quantity of peak current information signals that are at a logic high level among the plurality of peak current information signals. For example, the memory controller 1200 increases the period of the external clock signal as the quantity of peak current information signals at the logic high level increases.

Each of the plurality of memory devices 1100 generates an internal clock signal based on the external clock signal received from the memory controller 1200, and a period of the internal clock signal is proportional to a period of the external clock signal. Each of the plurality of memory devices 1100 performs various operations according to the generated internal clock signal, and current consumption decreases as the period of the internal clock signal increases or lengthens.

Therefore, the memory controller 1200 determines the quantity of memory devices 1100 with overlapping peak current intervals based on the plurality of peak current information signals and increases the period of the external clock signal as the quantity of memory devices 1100 having overlapping peak current intervals increases, thereby reducing the current consumption of the plurality of memory devices.

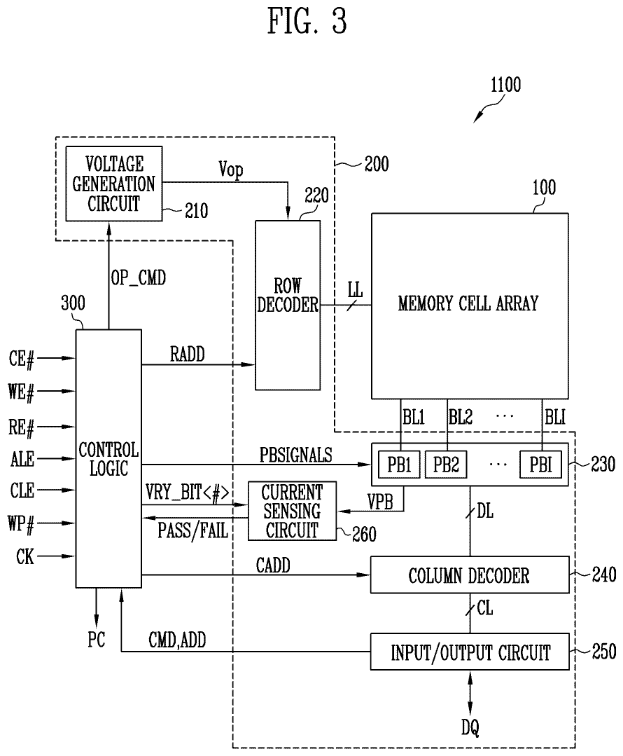

FIG. 3 is a detailed diagram of the memory device 1100, for example, as shown in FIG. 1.

The memory device 1100 may be a volatile memory device or a non-volatile memory device. For example, the memory device 1100 may be one of a volatile memory device such as Dynamic Random Access Memory (DRAM), Static RAM (SRAM), or the like, and a non-volatile memory device such as Read Only Memory (ROM), Mask ROM (MROM), Programmable ROM (PROM), Erasable ROM (EPROM), Electrically Erasable ROM (EEPROM), Ferromagnetic ROM (FRAM), Phase Change RAM (PRAM), Magnetic RAM (MRAM), Resistive RAM (RRAM), flash memory, or the like. FIG. 3 illustrates an example of a non-volatile memory device.

The memory device 1100 includes a memory cell array 100 in which data is stored. The memory device 1100 includes peripheral circuits 200 configured to perform a program operation to store data in the memory cell array 100, a read operation to output the stored data, and an erase operation to erase the stored data. The memory device 1100 includes a control logic circuit 300 that controls the peripheral circuits 200 under the control of memory controller 1200.

The memory cell array 100 includes a quantity of memory cells in which data is stored. For example, the memory cell array 100 includes at least one plane, each plane including one or more memory blocks. In an embodiment, the plane is a unit of memory that is accessed when a program, read, or erase operation is performed. A memory plane is referred to simply as a plane in the disclosure. Each of the memory blocks may include a plurality of memory cells. A structure with a plurality of planes is referred to as a multi-plane structure. The memory blocks store user data and information utilized during the operation on the memory device 1100. The memory blocks may have a two-dimensional or a three-dimensional structure. Memory blocks having a two-dimensional structure include memory cells arranged parallel to a substrate, and memory blocks having a three-dimensional structure include memory cells stacked perpendicular to or extending away from the substrate.

The control logic circuit 300 controls the peripheral circuits 200 to perform program, read, and erase operations. For example, the peripheral circuits 200 includes a voltage generation circuit 210, a row decoder 220, a page buffer group 230, a column decoder 240, an input/output circuit 250, and a current sensing circuit 260.

The voltage generation circuit 210 generates various operating voltages Vop used for program, read, and erase operations in response to an operating signal OP_CMD output from the control logic circuit 300. For example, the voltage generation circuit 210 generates various voltages, such as a program voltage, a verify voltage, a pass voltage, a read voltage, and an erase voltage, in response to control of the control logic circuit 300.

The row decoder 220, in response to a row address RADD output from the control logic circuit 300, supplies the operating voltages Vop to local lines LL coupled to a selected memory block among the memory blocks of the memory cell array 100. The local lines LL include, for example, local word lines, local drain select lines, and/or local source select lines. The local lines LL may include various lines coupled to a memory block, such as a source line.

The page buffer group 230 is coupled to bit lines BL1 to BLI coupled to the memory blocks of the memory cell array 100, where I is an integer greater than 1. The page buffer group 230 includes a plurality of page buffers PB1 to PBI coupled to corresponding bit lines BL1 to BLI. The page buffers PB1 to PBI operate in response to page buffer control signals PBSIGNALS output from the control logic circuit 300. For example, the page buffers PB1 to PBI temporarily store data received through the bit lines BL1 to BLI or may sense voltages or currents on the bit lines BL1 to BLI during a read or verify operation.

The column decoder 240 transfers data between the input/output circuit 250 and the page buffer group 230 in response to a column address CADD output from the control logic circuit 300. For example, the column decoder 240 exchanges data with the page buffers PB1 to PBI via data lines DL or exchanges data with the input/output circuit 250 via column lines CL.

The input/output circuit 250 receives a command CMD, an address ADD, and data from the memory controller 1200 via the input/output pad DQ and outputs data read from the memory cell array 100 to the memory controller 1200 through the input/output pad DQ. For example, the input/output circuit 250 communicate the command CMD and the address ADD received from memory controller 1200 to the control logic circuit 300 or exchanges data DATA with the column decoder 240.

The current sensing circuit 260 generates a reference current in response to an allowable bit VRY_BIT<#> during a read operation or a verify operation and compares a sensing voltage VPB received from the page buffer group 230 with a reference voltage generated by the reference current to output a pass signal PASS or a fail signal FAIL.

The control logic circuit 300 receives the command CMD and the address ADD in response to signals received through the CE #, WE #, RE #, ALE, CLE, and WP #pads. The control logic circuit 300, in response to receiving the command CMD and the address ADD, generates control signals that controls the peripheral circuits 200 and outputs the generated control signals to the peripheral circuits 200. For example, the control signals include at least one of the operating signal OP_CMD, the row address RADD, the page buffer control signals PBSIGNALS, and the allowable bit VRY_BIT<#>. The control logic circuit 300 outputs the operating signal OP_CMD to the voltage generation circuit 210, the row address RADD to the row decoder 220, the page buffer control signals PBSIGNALS to the page buffer group 230, and the allowable bit VRY_BIT<#> to the current sensing circuit 260. The control logic circuit 300 determines whether the verify operation passed or failed in response to the pass signal PASS or the fail signal FAIL.

The control logic circuit 300 generates an internal clock signal based on the external clock signal received through the CK pad. The control logic circuit 300 adjusts an activation interval and a deactivation interval of the control signals such as the operating signal OP_CMD, the row address RADD, the page buffer control signals PBSIGNALS, and the allowable bit VRY_BIT<#> based on the generated internal clock signal and outputs the control signals. The control logic circuit 300 adjusts or controls the period of the internal clock signal according to the period of the external clock signal and adjusts the period of the internal clock to control current consumption of the peripheral circuits 200.

The control logic circuit 300 generates a peak current information signal activated during a predetermined peak current interval during a program operation, a read operation, or an erase operation on the memory device 1100 and outputs the generated peak current information signal to the memory controller 1200 of FIG. 1 through the PC pad PC. For example, the control logic circuit 300 generates and output a peak current information signal that is activated at a logic high level during the predetermined peak current interval of various currently performed operations.

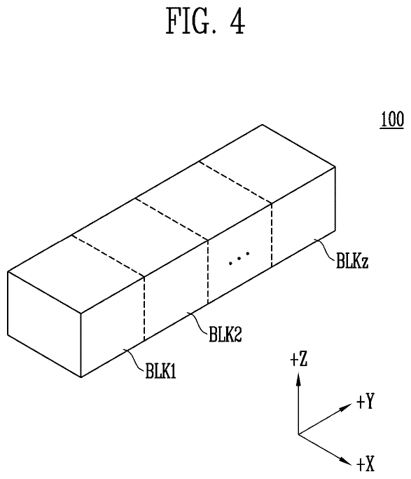

FIG. 4 is a diagram illustrating an embodiment of the memory cell array 100, for example, as shown in FIG. 3.

Referring to FIG. 4, the memory cell array 100 includes a plurality of memory blocks BLK1 to BLKz, where z is an integer. Each of the plurality of memory blocks BLK1 to BLKz has a three-dimensional structure. Each memory block includes a plurality of memory cells stacked on a substrate. The plurality of memory cells are arranged in an X direction, a Y direction, and a Z direction.

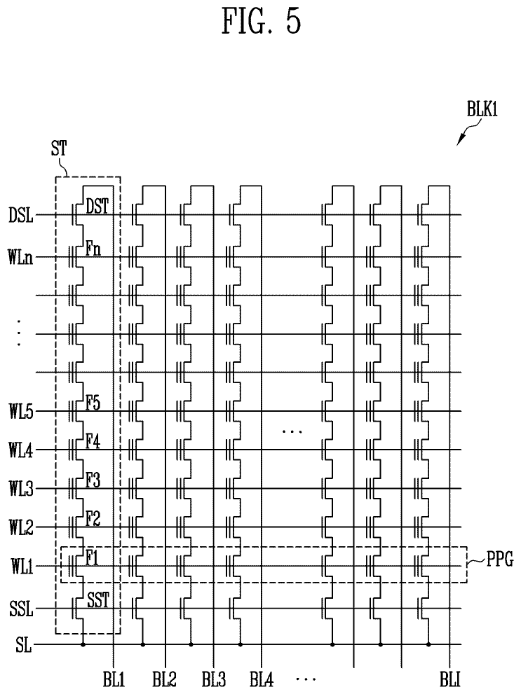

FIG. 5 is a diagram illustrating the first memory block BLK1, for example, as shown in FIG. 4.

Referring to FIG. 5, the first memory block BLK1 is shown among the plurality of memory blocks BLK1 to BLKz of FIG. 4. The memory blocks BLK2 to BLKz may have a similar structure as the first memory block BLK1.

The first memory block BLK1 includes a plurality of cell strings ST coupled between the bit lines BL1 to BLI and a source line SL. For example, each of the cell strings ST is coupled to a corresponding one of the bit lines BL1 to BLI and is commonly coupled to the source line SL. Because the cell strings ST are each configured similarly, the cell string ST coupled to the first bit line BL1 is described.

The cell string ST includes a source select transistor SST, first to n-th memory cells F1 to Fn, where n is a positive integer, and a drain select transistor DST coupled in series between the source line SL and the first bit line BL1. The quantities of source select transistors SST and drain select transistor DST are not limited to the quantities shown in FIG. 5. The source select transistor SST is coupled between the source line SL and the first memory cell F1. The first to n-th memory cells F1 to Fn are coupled in series between the source select transistor SST and the drain select transistor DST. The drain select transistor DST is coupled between the nth memory cell Fn and the first bit line BL1. Although not shown in FIG. 5, dummy cells may be coupled between the memory cells F1 to Fn or between the source select transistor SST and the drain select transistor DST.

Gates of the source select transistors SST included in different cell strings ST are coupled to a source select line SSL, gates of the memory cells F1 to Fn are coupled to first to nth word lines WL1 to WLn, and gates of the drain select transistors DST are coupled to drain select line DSL. A group of memory cells coupled to each of the word lines WL1 to WLn is referred to as a page PG. For example, a group of the first memory cells F1 coupled to the first word line WL1 among the first to n-th memory cells F1 to Fn included in the different cell strings ST is referred to as a physical page PPG. Program and read operations are performed on a physical page PPG basis.

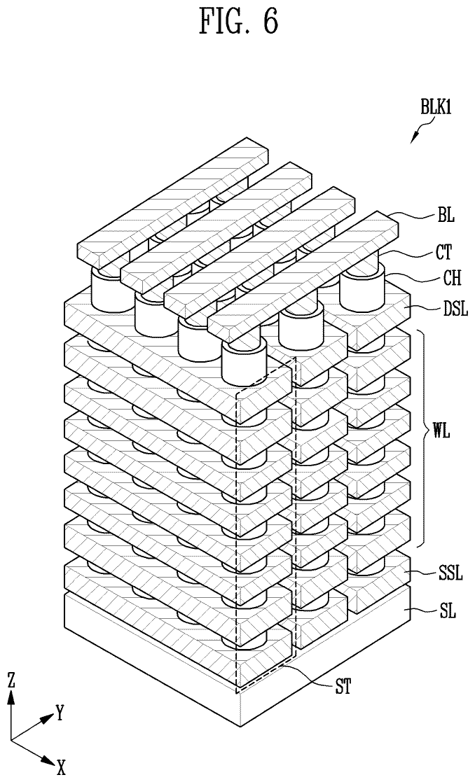

FIG. 6 is a diagram of the first memory block BLK1 configured in three dimensions, such as shown in FIG. 4.

Referring to FIG. 6, the first memory block BLK1 is shown among the plurality of memory blocks BLK1 to BLKz of FIG. 4. The memory blocks BLK2 to BLKz have a similar structure as the first memory block BLK1.

The first memory block BLK1 having a three-dimensional structure has an “I” shape in a vertical direction, the Z-direction, perpendicular to the substrate and includes the plurality of cell strings ST arranged between the bit lines BL and the source line SL. Alternatively, a well may be formed instead of the source line SL. This structure is referred to as Bit Cost Scalable (BiCS). For example, when the source line SL is formed horizontally on top of the substrate, the cell strings ST having a BiCS structure are formed in a direction, the Z direction, perpendicular to the top of the source line SL.

The cell strings ST are arranged in a first direction, the X direction, and a second direction, the Y direction. The cell strings ST include the source select lines SSL, word lines WL, and the drain select lines DSL are spaced apart and stacked, for example, formed in a vertical stack. The quantities of source select lines SSL, word lines WL, and drain select lines DSL are not limited to the quantities shown in FIG. 6 and may vary depending on the memory device 1100. The cell strings ST include vertical channel layers CH vertically extending through the source select lines SSL, the word lines WL, and the drain select lines DSL, and the bit lines BL contact the top of the vertical channel layers CH protruding above the drain select lines DSL extending in the first direction, the X direction. Memory cells are formed between the word lines WL and the vertical channel layers CH. A contact plug CT is formed between the bit lines BL and the vertical channel layers CH.

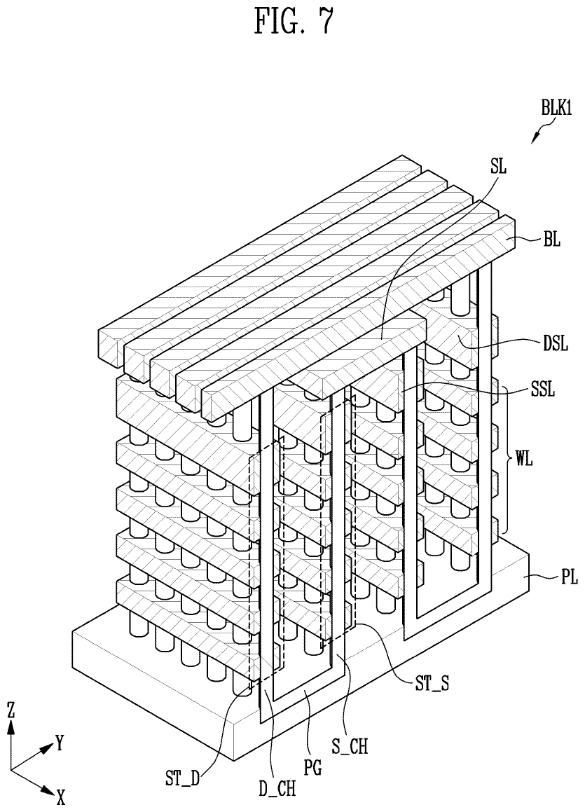

FIG. 7 is a diagram of another example of the first memory block BLK1 configured in three dimensions, for example, as shown in FIG. 4.

Referring to FIG. 7, the first memory block BLK1 is shown among the plurality of memory blocks BLK1 to BLKz shown in FIG. 4. The memory blocks BLK2 to BLKz have a similar structure as the first memory block BLK1.

The first memory block BLK1 having a three-dimensional structure is formed in a U-shape in a vertical direction, the Z-direction, on the substrate and includes paired source strings ST_S and drain strings ST_D coupled between the bit lines BL and the source line SL. The source strings ST_S are coupled to the drain strings ST_D through a pipe gate PG to form the U-shaped structure. The pipe gate PG is formed within a pipeline PL. The source strings ST_S are formed vertically between the source lines SL and the pipeline PL, and the drain strings ST_D are formed between the bit lines BL and the pipeline PL. This structure is referred to as Pipe-shaped Bit Cost Scalable (P-BiCS).

The drain strings ST_D and the source strings ST_S are arranged in the first direction, the X direction, and the second direction, the Y direction, and the drain strings ST_D are alternately arranged with the source strings ST_S in the second direction, the Y direction. The drain strings ST_D include the word lines WL stacked and spaced apart from the drain select line DSL, and drain vertical channel layers D_CH vertically extending through the word lines WL and the drain select line DSL. The source strings ST_S include the word lines WL stacked and spaced apart from the source select line SSL, and source vertical channel layers S_CH vertically extending through the word lines WL and the source selection line SSL. The drain vertical channel layers D_CH are coupled to the source vertical channel layers S_CH by the pipe gate PG within the pipeline PL. The bit lines BL contact a top of the drain vertical channel layers D_CH protruding above the drain select line DSL and extend in the second direction, the Y direction.

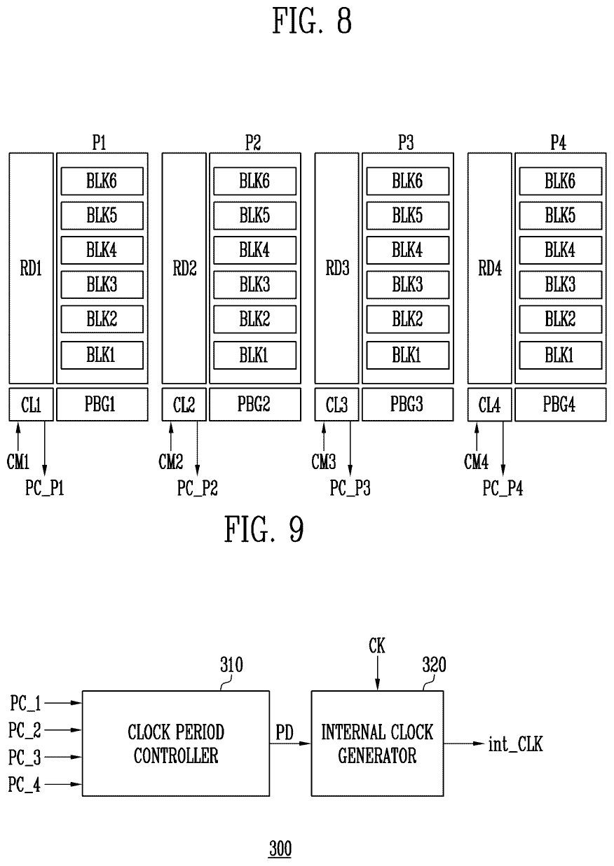

FIG. 8 is a diagram of a multi-plane structure in the memory device 1100, for example, as shown in FIG. 1.

Referring to FIG. 8, the memory cell array 100 of the memory device 1100 includes a plurality of planes P1 to P4. For example, first plane P1, the second plane P2, the third plane P3, and the fourth plane P4 are included in the memory cell array 100 in one memory device 1100.

Row decoders RD1 to RD4 and page buffer groups PBG1 to PBG4 are coupled to the planes P1 to P4, respectively, which planes P1 to P4 may operate independently. For example, the first plane P1 is operable in connection with the first row decoder RD1 and the first page buffer group PBG1, the second plane P2 is operable in connection with the second row decoder RD2 and the second page buffer group PBG2, the third plane P3 is operable in connection with the third row decoder RD3 and the third page buffer group PBG3, and the fourth plane P4 is operable with the fourth row decoder RD4 and the fourth page buffer group PBG4.

The first row decoder RD1 and the first page buffer group PBG1 are referred to as a first sub-peripheral circuit that performs various operations on the first plane P1, the second row decoder RD2 and the second page buffer group PBG2 are referred to as a second sub-peripheral circuit that performs various operations on the second plane P2, the third row decoder RD3 and the third page buffer group PBG3 are referred to as a third sub-peripheral circuit that performs various operations on the third plane P3, and the fourth row decoder RD4 and the fourth page buffer group PBG4 are referred to as a fourth sub-peripheral circuit that performs various operations on the fourth plane P4.

For example, during a read operation, each of the row decoders RD1 to RD4 applies a read voltage to a selected memory block in each of the planes P1 to P4 in response to the received row address. The page buffer groups PBG1 to PBG4 sense voltages or currents of the bit lines coupled to the planes P1 to P4 to temporarily store the read data. When all the sensing operations on the planes P1 to P4 are completed, the read data temporarily stored in the page buffer groups PBG1 to PBG4 are sequentially output by the input/output circuit 250. For example, after the read data of the first page buffer group PBG1 is output, the read data of the page buffer groups PBG2 to PBG4 are sequentially output.

The memory device 1100 including the plurality of planes P1 to P4 as shown in FIG. 8 performs a read operation, a program operation, and an erase operation on blocks or pages located in different planes concurrently or in parallel. For example, the control logic circuit 300 in FIG. 3 performs a plane interleaving operation in which memory operations such as program, read, or erase are performed concurrently, or in parallel, on memory blocks located in different planes.

To facilitate performing a plane interleaving operation, the control logic circuit 300 includes independent first to fourth sub-control logic circuits CL1 to CL4 corresponding to the first to fourth planes P1 to P4, respectively. For example, the first sub-control logic circuit CL1 controls operations on the first plane P1 in response to a first internal command CM1 corresponding to the first plane P1, and the second sub-control logic circuit CL2 controls operations on the second plane P2 in response to a second internal command CM2 corresponding to the second plane P2. The third sub-control logic circuit CL3 controls operations on the third plane P3 in response to the third internal command CM3 corresponding to the third plane P3, and the fourth sub-control logic circuit CL4 controls operations on the fourth plane P4 in response to the fourth internal command CM4 corresponding to the fourth plane P4. Thus, the decoders RD1 to RD4 and the page buffers PBG1 to PBG4 are independently controlled by the sub-control logic circuits CL1 to CL4, respectively. Thus, the first sub-peripheral circuit, the second sub-peripheral circuit, the third sub-peripheral circuit, and the fourth sub-peripheral circuit may be independently controlled by the first sub-control logic circuit CL1, the second sub-control logic circuit CL2, the third sub-control logic circuit CL3, and fourth sub-control logic circuit CL4, respectively.

When the command CMD received from the memory controller 1200 of FIG. 1 corresponds to a plane interleaving operation, the control logic circuit 300 generates the internal commands CM1 to CM4 in response to the command CMD.

The sub-control logic circuits CL1 to CL4 generate peak current information signals PC_P1 to PC_P4 corresponding to the planes P1 to P4, respectively. For example, the first sub-control logic circuit CL1 generates the first peak current information signal PC_P1 at a logic high level during a peak current interval while any of the various operations are performed on the first plane P1, and the second sub-control logic circuit CL2 generates the logic low-level second peak current information signal PC_P2 at a logic high level during a peak current interval while any of the various operations are performed on the second plane P2. The third sub-control logic circuit CL3 generates the third peak current information signal PC_P3 at a logic high level during a peak current interval while any of the various operations are performed on the third plane P3, and the fourth sub-control logic circuit CL4 generates the fourth peak current information signal PC_P4 at a logic high level during a peak current interval while any of the various operations are performed on the fourth plane P4. The peak current interval of each operation may be predetermined and stored in each of the sub-control logic circuits CL1 to CL4.

At least one of the sub-control logic circuits CL1 to CL4 is integrated such that one sub-control logic circuit is configured to control two or more planes.

FIG. 9 is a diagram illustrating an embodiment of the control logic circuit 300, for example, as shown in FIG. 3.

Referring to FIG. 9, the control logic circuit 300 includes a clock period controller 310 and an internal clock generator 320 in addition to the sub-control logic circuits CL1 to CL4 of FIG. 8.

The clock period controller 310 receives the peak current information signals PC_P1 to PC_P4 generated by the sub-control logic circuits CL1 to CL4 and determines an internal clock signal period based on the received peak current information signals PC_P1 to PC_P4.

For example, the clock period controller 310 determines an interval during which logic high-level intervals of the received peak current information signals PC_P1 to PC_P4 overlap, and determines a clock period during the overlapped interval, which determined clock period is longer than a base period. When the logic high-level intervals of the at least two peak current information signals overlap, the clock period controller 310 increases the clock period as the quantity of overlapping signals increases. The clock period controller 310 outputs, to the internal clock generator 320, an internal clock period information signal PD based on the peak current information signals PC_P1 to PC_P4.

The internal clock generator 320 receives an external clock signal through the CK pad CK and generates an internal clock signal int_CLK based on the external clock signal. The internal clock generator 320 receives the internal clock period information signal PD from the clock period controller 310 and generates the internal clock signal int_CLK having a base period or a period longer than the base period based on the internal clock period data signal PD.

The control logic circuit 300 uses the generated internal clock signal int_CLK to generate the operating signal OP_CMD, the row address RADD, and the page buffer control signals PBSIGNALS that control the peripheral circuits 200 of FIG. 3.

The sub-control logic circuits CL1 to CL4 of FIG. 8 generate control signals that control the row decoders RD1 to RD4 and the page buffers PBG1 to PBG4 according to the generated internal clock signal int_CLK.

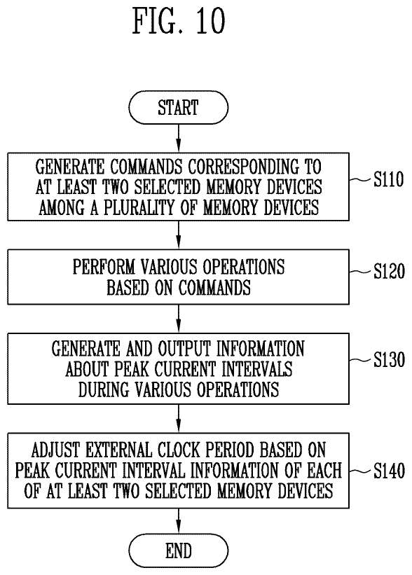

FIG. 10 is a flowchart illustrating a method of operating a memory system according to an embodiment of the present disclosure. The processes of the flowchart may be performed in a different order and may include fewer or additional processes than described and shown in FIG. 10.

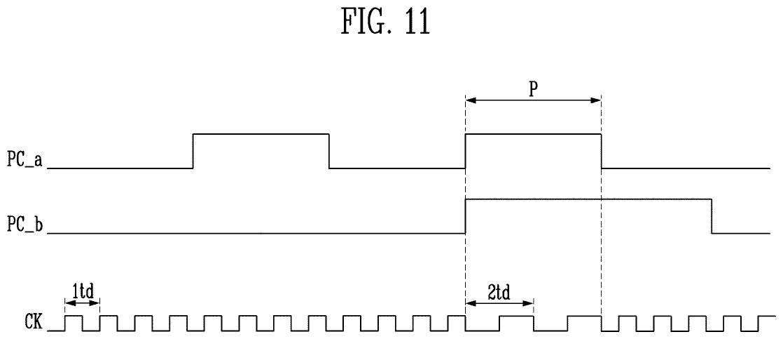

FIG. 11 is a timing diagram including signals during a method of operating a memory system according to an embodiment of the present disclosure.

A method of operating a memory system according to an embodiment of the present disclosure is described with reference to FIG. 1 to FIG. 11.

The memory controller 1200 generates S110 a plurality of commands that control various operations on each of at least two or more memory devices among the plurality of memory devices 1100 and transfers the generated commands among at least two selected memory devices.

For example, the memory controller 1200 generates commands to control various operations including a program operation, a read operation, and an erase operation on each of a plurality of memory devices coupled to different channels. For example, the memory controller 1200 generates a command corresponding to a program operation on the memory device 1100 coupled to the first channel CH1 and a command corresponding to a read operation on the memory device 1100 coupled to a second channel CH2 and transfers the generated commands to the memory device 1100 coupled to the first channel CH1 and the memory device 1110 coupled to the second channel CH2.

The memory device 1100 that receives the command CMD from the memory controller 1200 performs S120 various operations corresponding to the command CMD based on the received command CMD, such as a program operation, a read operation, or an erase operation.

The memory device 1100 receives the external clock signal from the memory controller 1200 during various operations and generates the internal clock signal based on the received external clock signal. The memory device 1100 generates the operating signal OP_CMD, the row address RADD, and the page buffer control signals PBSIGNALS that control the peripheral circuits 200 to perform various operations according to the generated internal clock signal.

The control logic circuit 300 of the memory device 1100 generates and outputs S130 peak current information during various operations. For example, the control logic circuit 300 generates and outputs a peak current information signal PC that is activated at a logic high-level during an interval in which the amount of current consumed by the memory device 1100 exceeds a predetermined value during various operations.

Each of at least two or more memory devices, included in the plurality of memory device groups 1300 and performing various operations, generates and outputs a peak current information signal PC. For example, a first memory device 1100 of the two or more memory devices generates and outputs a first peak current information signal PC_a, and a second memory device 1110 generates and outputs a second peak current information signal PC_b.

The memory controller 1200 receives the peak current information signals PC (PC_a and PC_b) from each of the two or more selected memory devices performing the various operations and adjusts S140 the external clock signal period based on the received peak current information signals PC (PC_a and PC_b).

For example, when intervals during which the received peak current information signals PC are activated at a logic high level overlap, the memory controller 1200 generates an external clock signal period by increasing the external clock signal period to a period longer than a base period 1td during interval P in which the peak current intervals of the selected memory devices overlap. For example, the memory controller 1200 generates and outputs an external clock signal having a period 2td that is longer than the base period 1td during interval P in which the first peak current information signal PC_a is at a logic high level while the second peak current information signal PC_b is at a logic high level.

The memory controller 1200 determines the quantity of memory devices with overlapping peak current intervals based on the quantity of peak current information signals PC in which the peak current information signals PC are activated at the logic high level during overlapping intervals and generates the external clock signal period by increasing the external clock signal period based on the quantity of peak current information signals PC with overlapping intervals during which the peak current information signals PC are activated at the logic high level. For example, the period of the external clock signal when the activated intervals of three peak current information signals PC overlap is longer than the period of the external clock signal when the activated intervals of two peak current information signals PC overlap.

Each of the at least two selected memory devices 1100, 1110 receives, from the memory controller 1200, the external clock signal with an adjusted period and adjusts the period of the internal clock signal according to the received external clock signal. Each of the two or more selected memory devices 1100 reduces the amount of current consumed during various operations according to the internal clock signal with the adjusted period.

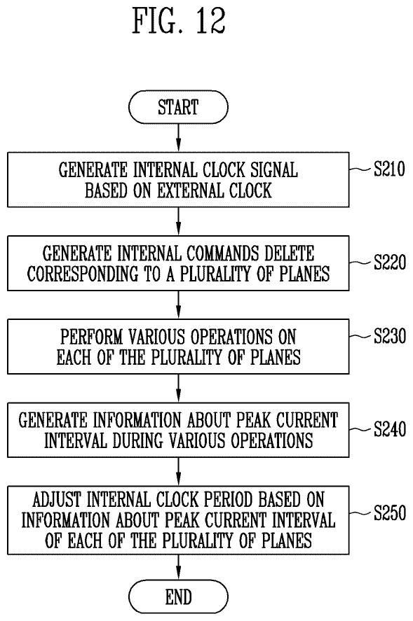

FIG. 12 is a flowchart illustrating a method of operating a memory device according to an embodiment of the present disclosure. The processes of the flowchart may be performed in a different order and may include fewer or additional processes than described and shown in FIG. 12.

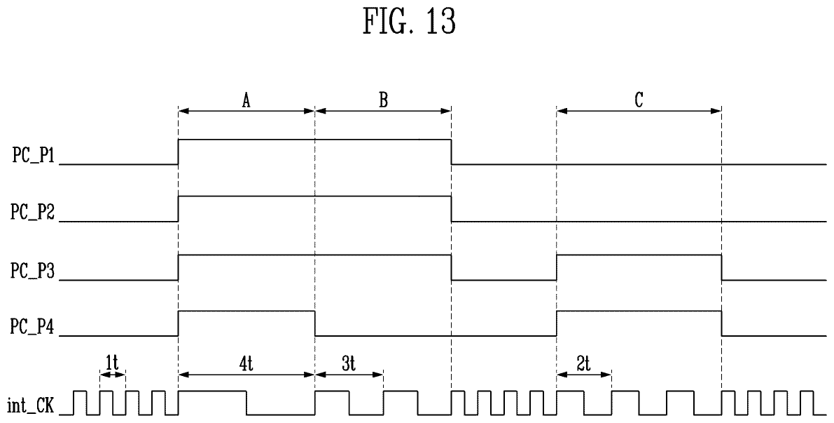

FIG. 13 is a timing diagram including signals during a method of operating a memory device according to an embodiment of the present disclosure.

Referring to FIG. 1 to FIG. 9, FIG. 12, and FIG. 13, a method of operating a memory device according to an embodiment of the present disclosure is described.

The memory device 1100 receives an external clock signal from the memory controller 1200 and generates S210 the internal clock signal int_CLK having a period or cycle based on the received external clock signal. For example, the internal clock generator 320 of the control logic circuit 300 generates the internal clock signal int_CLK having a period based on the received external clock signal.

The memory device 1100 receives the command CMD and the address ADD from the memory controller 1200 and generates S220 internal commands corresponding to each of the plurality of planes when the received command CMD corresponds to a plane interleaving operation in which a program, read, or erase operation is performed concurrently, or in parallel, on the plurality of planes P1 to P4. When the command CMD received from the memory controller 1200 of FIG. 1 corresponds to a plane interleaving operation, the control logic circuit 300 generates the internal commands CM1 to CM4 in response to the command CMD.

Various operations corresponding to the internal commands CM1 to CM4 are performed S230 on the plurality of planes P1 to P4.

For example, the first sub-control logic circuit CL1 controls operations on the first plane P1 in response to the first internal command CM1 corresponding to the first plane P1, and the second sub-control logic circuit CL2 controls operations on the second plane P2 in response to the second internal command CM2 corresponding to the second plane P2. The third sub-control logic circuit CL3 controls operations on the third plane P3 in response to the third internal command CM3 corresponding to the third plane P3, and the fourth sub-control logic circuit CL4 controls operations on the fourth plane P4 in response to the fourth internal command CM4 corresponding to the fourth plane P4. Thus, the row decoders RD1 to RD4 and the page buffers PBG1 to PBG4 may be independently controlled by the sub-control logic circuits CL1 to CL4, respectively, to perform various operations on the plurality of planes P1 to P4 concurrently or in parallel.

The plurality of sub-control logic circuits CL1 to CL4 generate S240 and output the peak current information signals PC_P1, PC_P2, PC_P3, and PC_P4 during various operations on the plurality of planes P1 to P4. For example, the plurality of sub-control logic circuits CL1 to CL4 generates and outputs corresponding peak current information signals PC_P1, PC_P2, PC_P3, and PC_P4 that are activated at a logic high level during an interval in which the amount of current consumed exceeds a predetermined value during various operations on each of the plurality of corresponding planes P1 to P4. For example, the first sub-control logic circuit CL1 generates the first peak current information signal PC_P1 activated at a logic high-level during a peak current interval in which the amount of current consumed during various operations on the first plane P1 exceeds the predetermined value. For example, the second sub-control logic circuit CL2 generates the second peak current information signal PC_P2 activated at a logic high-level during a peak current interval in which the amount of current consumed during various operations on the second plane P2 exceeds the predetermined value. For example, the third sub-control logic circuit CL3 generates the third peak current information signal PC_P3 activated at a logic high-level during a peak current interval in which the amount of current consumed during various operations on the third plane P3 exceeds the predetermined value. For example, the fourth sub-control logic circuit CL4 generates the fourth peak current information signal PC_P4 activated at a logic high-level during a peak current interval in which the amount of current consumed during various operations on the fourth plane P4 exceeds the predetermined value. Thus, the peak current information signals PC_P1, PC_P2, PC_P3, and PC_P4 indicate information on or regarding a peak current interval for each of the plurality of planes P1 to P4.

The control logic circuit 300 adjusts S250 the period of the internal clock signal int_CLK based on information about the peak current intervals of the plurality of planes P1 to P4.

For example, the control logic circuit 300 determines an interval in which peak current intervals of the plurality of planes P1 to P4 overlap based on the generated peak current information signals PC_P1, PC_P2, PC_P3, and PC_P4.

For example, the clock period controller 310 of the control logic circuit 300 receives the peak current information signals PC_P1 to PC_P4 generated by the sub-control logic circuits CL1 to CL4, determines an interval during which the logic high-level intervals of the received peak current information signals PC_P1 to PC_P4 overlap, determines a clock period longer than a base period for use during the interval of overlap, and outputs the internal clock period information signal PD to the internal clock generator 320. When the logic high-level intervals of the at least two peak current information signals overlap, the clock period controller 310 increases the clock period as the quantity of overlapping signals increases.

The internal clock generator 320 receives an external clock signal through the CK pad CK, generates the internal clock signal int_CLK based on the external clock signal, receives the internal clock period information signal PD from the clock period controller 310, and generates the internal clock signal int_CLK having a base period or a period longer than the base period based on the internal clock period information signal PD.

Referring to FIG. 13, during interval A, the first peak current information signal PC_P1, the second peak current information signal PC_P2, the third peak current information signal PC_P3, and the fourth peak current information signal PC_P4 are activated at a logic high level, and the peak current interval of the first plane P1, the peak current interval of the second plane P2, the peak current interval of the third plane P3, and the peak current interval of the fourth plane P4 overlap. Therefore, the clock period controller 310 applies a period 4t that is longer than the base period 1t during interval A to output the internal clock period information signal PD, and the internal clock generator 320 generates the internal clock signal int_CLK having the period 4t in response to or based on the internal clock period information signal PD.

During interval B, the first peak current information signal PC_P1, the second peak current information signal PC_P2, and the third peak current information signal PC_P3 are activated at a logic high level, and the peak current interval of the first plane P1, the peak current interval of the second plane P2, and the peak current interval of the third plane P3 overlap. Therefore, the clock period controller 310 applies a period 3t that is longer than the base period 1t during interval B to output the internal clock period information signal PD, and the internal clock generator 320 generates the internal clock signal int_CLK having the period 3t in response to or based on the internal clock period information signal PD. The period 3t is shorter than the period 4t. During interval B, because the peak current intervals of three planes overlap, the period is shorter than the period during interval A when peak current intervals of four planes overlap.

During interval C, the third peak current information signal PC_P3 and the fourth peak current information signal PC_P4 are activated at a logic high level, and the peak current interval of the third plane P3 and the peak current interval of the fourth plane P4 overlap. Therefore, the clock period controller 310 applies the period 2t that is longer than the base period 1t during interval C to output the internal clock period information signal PD, and the internal clock generator 320 generates the internal clock signal int_CLK having the period 2t in response to or based on the internal clock period information signal PD. The period 2t is shorter than the period 3t. During interval C, because the peak current intervals of two planes overlap, the period is shorter than the period during interval B when peak current intervals of three planes overlap.

The sub-control logic circuits CL1 to CL4 perform various operations on the planes P1 to P4 by controlling the row decoders RD1 to RD4 and the page buffers PBG1 to PBG4 according to the generated internal clock signal int_CLK.

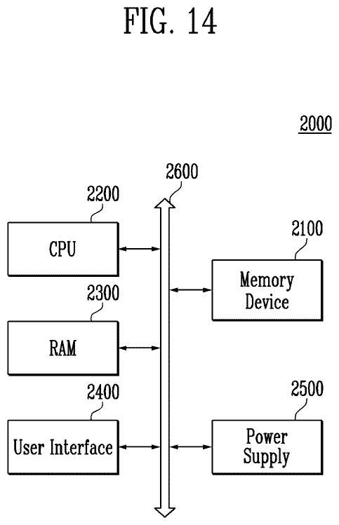

FIG. 14 is a block diagram illustrating a configuration of a computing system 2000 according to an embodiment.

Referring to FIG. 14, the computing system 2000 includes a memory device 2100, a CPU 2200, a random-access memory (RAM) 2300, a user interface 2400, a power supply 2500, and a system bus 2600.

The memory device 2100 stores data provided via the user interface 2400, data processed by the CPU 2200, and so forth. The memory device 2100 is electrically coupled to the CPU 2200, the RAM 2300, the user interface 2400, and the power supply 2500 by the system bus 2600. For example, the memory device 2100 is coupled to the system bus 2600 via a controller (not shown) or directly to the system bus 2600. When the memory device 2100 is directly coupled to the system bus 2600, functions of the controller are performed by the CPU 2200 and the RAM 2300.

The memory device 2100 may be a non-volatile memory. The memory device 2100 may be memory device such as described with reference to FIG. 3. When peak current intervals of a plurality of memory devices 2100 overlap, an external clock signal period applied to each of the plurality of memory devices 2100 may be adjusted to reduce a peak current of computing system 2000.

The computing system 2000 having the as shown in FIG. 14 may be utilized in an electronic device such as a computer, an ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices that form a home network, one of various electronic devices that form a computer network, one of various electronic devices that form a telematics network, an RFID device, or the like.

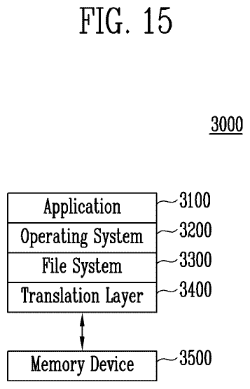

FIG. 15 is a block diagram illustrating a computing system 3000 according to an embodiment.

Referring to FIG. 15, the computing system 3000 according to an embodiment includes a software layer that has an operating system 3200, an application layer 3100, a file system 3300, and a translation layer 3400. The computing system 3000 includes a hardware layer such as a memory device 3500.

The operating system 3200 manages software and hardware resources of the computing system 3000. The operating system 3200 controls program execution of a central processing unit. The application layer 3100 includes various application programs executed by the computing system 3000. The application layer 3100 may be a utility executed by the operating system 3200.

The file system 3300 refers to a logical structure configured to manage data and files present in the computing system 3000. The file system 3300 organizes files or data and stores the result in the memory device 3500 according to established guidelines or rules. The file system 3300 may depend on the operating system 3200 used in the computing system 3000. For example, when the operating system 3200 is a Microsoft Windows-based system, the file system 3300 may be a file allocation table (FAT) or an NT file system (NTFS). When the operating system 3200 is a Unix/Linux system, the file system 3300 may be an extended file system (EXT), a Unix file system (UFS), a journaling file system (JFS), or the like.

FIG. 15 illustrates the operating system 3200, the application layer 3100, and the file system 3300 in separate blocks. The application layer 3100 and the file system 3300 may be included in the operating system 3200.

The translation layer 3400 translates an address into a suitable form for the memory device 3500 in response to a request from the file system 3300. For example, the translation layer 3400 translates a logic address, generated by the file system 3300, into a physical address of the memory device 3500. Mapping information including the logical address and the physical address is stored in an address translation table. For example, the translation layer 3400 may be a flash translation layer (FTL), a universal flash storage link layer (ULL), or the like.

The memory device 3500 may be a non-volatile memory. The memory device 3500 may be a memory device such as described with reference to FIG. 3. When peak current intervals of a plurality of memory devices 3500 overlap, an external clock signal period applied to each of the plurality of memory devices 3500 may be adjusted to reduce a peak current of computing system 3000.

The computing system 3000 as shown in FIG. 15 may be divided into an operating system layer that is operated in an upper layer region and a controller layer that is operated in a lower level region. The application layer 3100, the operating system 3200, and the file system 3300 may be included in the operating system layer, and may be driven by operating memory of the computing system 3000. The translation layer 3400 may be included in the operating system layer or the controller layer.

According to the present disclosure, when peak current intervals of a plurality of planes operating in an interleaved manner overlap, an internal clock signal period of a memory device may be adjusted to reduce a peak current of the memory device.

When peak current intervals of a plurality of memory devices overlap, an external clock signal period applied to each of the plurality of memory devices may be adjusted to reduce a peak current of a memory system.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A memory device comprising:
a plurality of memory planes, each including a plurality of memory blocks;
a plurality of sub-peripheral circuits, each corresponding to one of the plurality of memory planes, each of the plurality of sub-peripheral circuits configured to perform various operations on a selected memory block included in a corresponding plane among the plurality of memory planes; and
a plurality of sub-control logic circuits, each configured to control one of the plurality of sub-peripheral circuits;
wherein the plurality of sub-control logic circuits is configured to generate peak current information signals activated during peak current intervals during any of the various operations on the plurality of memory planes; and
wherein a period of an internal clock signal is adjusted based on the peak current information signals.

2. The memory device of claim 1, further comprising:
a clock period controller configured to determine the period of the internal clock signal based on the peak current information signals and output an internal clock period information signal; and
an internal clock generator configured to generate the internal clock signal based on an external clock signal and adjust the period of the internal clock signal based on the internal clock period information signal.

3. The memory device of claim 2, wherein the clock period controller increases the period of the internal clock signal to a period longer than a base period during one of the peak current intervals in which the activated peak current information signals overlap.

4. The memory device of claim 2, wherein the clock period controller increases the period of the internal clock signal as a quantity increases of the activated peak current information signals that overlap during one of the peak current intervals.

5. The memory device of claim 1, wherein the plurality of sub-peripheral circuits perform a plane interleaving operation on the selected memory block included in each of the plurality of memory planes.

6. The memory device of claim 1, wherein the plurality of sub-control logic circuits are configured to generate control signals that control the plurality of sub-peripheral circuits according to the internal clock signal.

7. A method of operating a memory device, the method comprising:
generating an internal clock signal based on an external clock signal;
generating a plurality of internal commands that control various operations on each of a plurality of memory planes;
performing the various operations on the plurality of memory planes concurrently in an interleaved manner based on the plurality of internal commands;
generating a plurality of peak current information signals corresponding to the plurality of memory planes and including information on peak current intervals during any of the various operations on the plurality of memory planes; and
adjusting a period of the internal clock signal based on the plurality of peak current information signals.

8. The method of claim 7, wherein each of the plurality of peak current information signals is activated at a logic high level during a peak current interval on a corresponding memory plane among the plurality of memory planes.

9. The method of claim 8, wherein the adjusting the period of the internal clock signal based on the plurality of peak current information signals comprises:
determining an interval in which two or more of the plurality of peak current information signals are activated and overlap; and
increasing the period of the internal clock signal to a period longer than a base period during the interval.

10. The method of claim 9, wherein adjusting the period of the internal clock signal based on the plurality of peak current information signals comprises increasing the period of the internal clock signal as a quantity increases of the activated peak current information signals that overlap during one of the peak current intervals.

11. The method of claim 7, further comprising generating control signals that control the various operations on the plurality of memory planes according to the internal clock signal.

12. A memory system comprising:
a plurality of memory devices; and
a memory controller configured to control various operations on the plurality of memory devices;
wherein each of the plurality of memory devices is configured to generate and output information about a peak current interval during the various operations; and
wherein the memory controller is configured to generate and output an external clock signal having an adjusted period based on information about the peak current interval received from each of the plurality of memory devices.

13. The memory system of claim 12, wherein each of the plurality of memory devices is configured to generate an internal clock signal based on the external clock signal.

14. The memory system of claim 13, wherein each of the plurality of memory devices is configured to generate control signals to perform the various operations according to the internal clock signal.

15. The memory system of claim 12, wherein the memory controller is configured to determine an interval in which peak current intervals overlap during the various operations on the plurality of memory devices based on the information about the peak current intervals of the plurality of memory devices and increases a period of the external clock signal during the interval.

16. The memory system of claim 12, wherein the memory controller determines an interval in which peak current intervals overlap during the various operations on the plurality of memory devices based on the information about the peak current intervals of the plurality of memory devices and increases a period of the external clock signal based on a quantity of memory devices having the peak current intervals that overlap during the interval.

17. A method comprising:
generating an internal clock signal based on an external clock signal;
generating a plurality of commands that control a plurality of operations concurrently performed on each of a plurality of memory planes;
generating a plurality of peak current information signals including information on a peak current intervals during the plurality of operations; and
adjusting a period of the internal clock signal based on the plurality of peak current information signals.
